(19) United States
(12) Patent Application Publication
(10) Pub. No.: US 2014/0283991 A1
(43) Pub. Date: Sep. 25, 2014

(54) Wafer Edge Protector

(71) Applicant: WIN SEMICONDUCTORS CORP., Tao Yuan Shien (TW)

(72) Inventors: Chia-Hao CHEN, Tao Yuan Shien (TW); Yi-Feng WEI, Tao Yuan Shien (TW); Yao-Chung HSIEH, Tao Yuan Shien (TW); I Te CHO, Tao Yuan Shien (TW); Walter Tony WOHLMUTH, Tao Yuan Shien (TW)

(73) Assignee: WIN Semiconductors Corp., Tao Yuan Shien (TW)

(21) Appl. No.: 13/847,679

(22) Filed: Mar. 20, 2013

(51) Int. Cl. H01L 21/67

(52) U.S. Cl. CPC H01L 21/67069
USPC 156/345.3

(57) ABSTRACT

A wafer edge protector is used in an inductively coupled plasma reactive ion etching instrument for the manufacturing of GaN semiconductor devices and circuits. The wafer edge protector comprises a ring clamp, which has a first inner diameter and a second inner diameter, and the ring clamp covers the edges of a wafer and a wafer carrier to clamp the wafer and the wafer carrier and to prevent damage on the edges of the wafer and the wafer carrier during the etching process.

### FIELD OF THE INVENTION

The present invention relates to a wafer edge protector, and more particular to a wafer edge protector used in an inductively coupled plasma reactive ion etching instrument for the manufacturing of GaN semiconductor devices and circuits.

### BACKGROUND OF THE INVENTION

The inductively coupled plasma reactive ion etching technology is usually applied in the manufacturing processes of compound semiconductor wafer. During the etching process, the compound semiconductor wafer has to be mounted on a wafer carrier first. The wafer and the wafer carrier are then fixed in the etching instrument for etching. In a previous technology, the wafer clamp used to fix the wafer and wafer carrier in the etching instrument is a multiple-finger wafer clamp, which usually comprises 6 or 8 clamping fingers arranged in a circle for clamping the wafer and the wafer carrier. The input RF bias, for the back side via etching, must be high which often causes damage on the wafer edge. The product yield is thereby limited. By exposure to the plasma, the edge of the wafer carrier is also damaged and needs to be replaced frequently, which increases the manufacturing cost.

### SUMMARY OF THE INVENTION

The main objective of the present invention is to provide a wafer edge protector used in an inductively coupled plasma reactive ion etching (ICP-RIE) instrument to avoid damage of the wafer edge and to prevent damage of the wafer carrier by the etching materials. This invention enables the product yield to be improved, the lifetime of the wafer carrier can be extended, and the manufacturing cost can be reduced.

To reach the objective stated above, the present invention provides a wafer edge protector which is used in an inductively coupled plasma reactive ion etching instrument. The wafer edge protector comprises a ring clamp, which has a first inner diameter and a second inner diameter. The ring clamp covers the edges of a wafer and a wafer carrier to clamp the wafer and the wafer carrier and to prevent damage on the edges of the wafer and the wafer carrier during the etching process.

In implementation, the first inner diameter ranges from 50 mm to 200 mm.

In implementation, the second inner diameter ranges from 50 mm to 1000 mm.

In implementation, the ring clamp is made of ceramic material.

In implementation, the wafer is a compound semiconductor GaN wafer of size ranging from 50 mm to 200 mm.

In implementation, the compound semiconductor GaN wafer is bonded on a wafer carrier of size ranging from 50 mm to 200 mm

In implementation, the wafer carrier for a compound semiconductor GaN wafer is made of a sapphire wafer, a glass wafer, or a SiC wafer.

The present invention will be understood more fully by reference to the detailed description of the drawings and the preferred embodiments below.

### BRIEF DESCRIPTION OF DRAWINGS

FIG. 1A-1C are schematics showing an embodiment of a wafer edge protector provided by the present invention and a cross-sectional view and a partial enlargement of the embodiment.

### DETAILED DESCRIPTIONS OF PREFERRED EMBODIMENTS

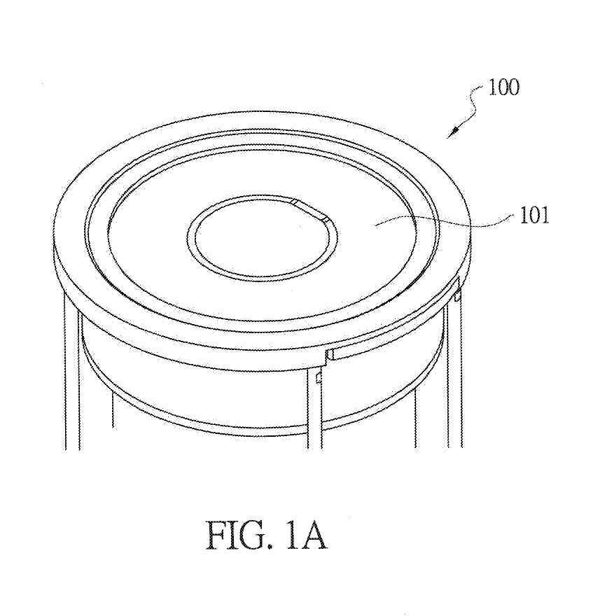

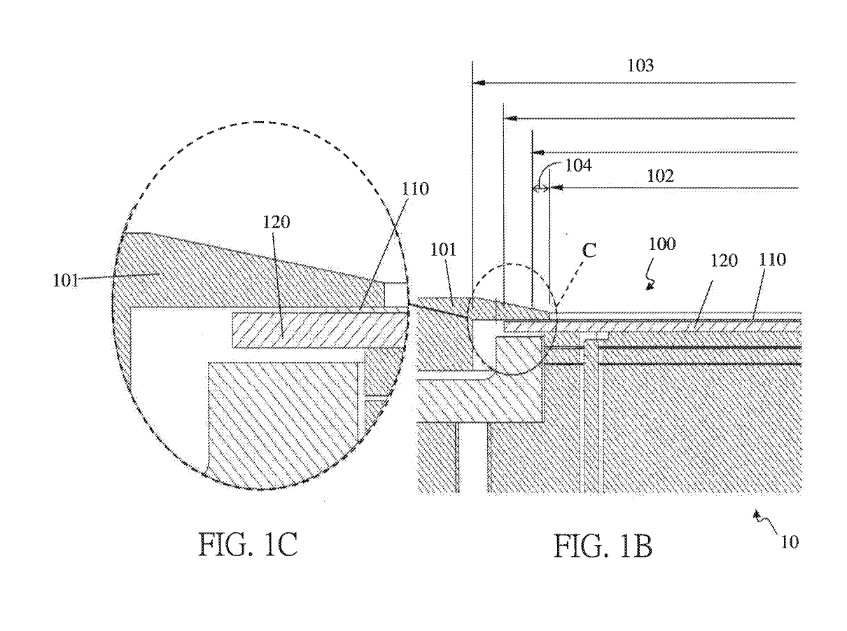

FIG. 1A-1C are schematics showing an embodiment of a wafer edge protector 100 provided by the present invention, in which FIG. 1C is a partial enlargement of the dashed circle C in FIG. 1B. The wafer edge protector 100 is used in an inductively coupled plasma reactive ion etching (ICP-RIE) instrument 10. The wafer edge protector comprises a ring clamp 101, which has a first inner diameter 102 and a second inner diameter 103. The ring clamp 101 covers the edges of a semiconductor wafer 110 and a wafer carrier 120 to clamp the semiconductor wafer 110 and the wafer carrier 120 and to prevent damage on the edges of the semiconductor wafer 110 and the wafer carrier 120 during the etching process.

In the embodiment provided by the present invention, the first inner diameter 102 forms an etching region for the semiconductor wafer, and the second inner diameter 103 should be able to contain the wafer and the wafer carrier. The wafer edge protector provided by the present invention can be used in the manufacturing process of compound semiconductor GaN wafers of the size ranging from 2 inches (50 mm) to 8 inches (200 m). The GaN wafer is comprised of GaN-based epitaxial layers grown on a semi-insulating SiC 411 or 6H substrate. The size of the wafer carrier must be equal to or larger than the wafer it carries. Accordingly, the first inner diameter can range from 50 mm to 200 mm, and the second inner diameter can range from 50 mm to 1000 mm. The mainstream product of GaN wafers at present is the 4-inch GaN wafer. Considering the 4-inch GaN wafers, the commonly used wafer carriers are conductive materials composed of either sapphire wafer carriers, glass wafer carriers, or SIC wafer carriers of the size ranging from 4 inches (100 mm) to 8 inches (200 mm). In the most preferred embodiment of a 4-inch wafer according to the present invention, the first inner diameter 102 ranges from 90 to 100 mm, and the second inner diameter 103 ranges from 100 to 200 mm. For a 4-inch wafer in this embodiment, the wafer edge covered by the wafer edge protector ranges from 1.5 to 5.0 mm. The range of the first and the second inner diameters in the embodiments of the present invention can be adjusted according to the size of the wafer and the wafer carrier. For good protection of the edges of the wafer and the wafer carrier, the ring clamp 101 is made preferably of materials of high hardness, high etch resistance, and high corrosion resistance, most preferably of ceramic materials.

Thereby, by covering the edges of the wafer and the wafer carrier, the wafer edge protector provided by the present invention can prevent damage at the edges of the wafer and the wafer carrier. Since the edges of the wafer and the wafer carrier are both covered, the exposure of the adhesive or wax for bonding the wafer and the wafer carrier can be prevented, and thus the contamination of wafer caused by the leakage of adhesive or wax can be avoided. Furthermore, the damage of the wafer carrier by the etching materials can also be avoided.

To sum up, the present invention can indeed get its anticipated objective to provide a wafer edge protector used in an inductively coupled plasma reactive ion etching (ICP-RIE) instrument to avoid damage at the edges of the wafer carrier. The product yield can thus be improved, the lifetime of the wafer carrier can be extended, and the manufacturing cost can be reduced.

The description referred to the drawings stated above is only for the preferred embodiments of the present invention. Many equivalent variations and modifications can still be made by those skilled at the field related with the present invention and do not depart from the spirit of the present invention, so they should be regarded to fall into the scope defined by the appended claims.

What is claimed is:

1. A wafer edge protector, used in an inductively coupled plasma reactive ion etching instrument, the wafer edge protector having a ring clamp, wherein the ring clamp has a first inner diameter and a second inner diameter, and the ring clamp covers the edges of a wafer and a wafer carrier to clamp the water and the wafer carrier and to prevent damage on the edges of the wafer and the wafer carrier during the etching process.

2. The wafer edge protector according to claim 1, wherein the first inner diameter is ranging from 40 mm to 200 mm.

3. The wafer edge protector according to claim 1, wherein the second inner diameter is ranging from 50 mm to 1000 mm.

4. The wafer edge protector according to claim 1, wherein the ring clamp is made of ceramic materials.

5. The wafer edge protector according to claim 1, wherein the wafer is a compound semiconductor GaN wafer of size ranging from 50 mm to 200 mm.

6. The wafer edge protector according to claim 5, wherein the GaN wafer is comprised of GaN-based epitaxial layers grown on a semi-insulating SiC 4H or 6H substrate,

7. The wafer edge protector according to claim 6, wherein the compound semiconductor GaN wafer is bonded on a wafer carrier of size ranging from 50 mm to 200 mm.

8. The wafer edge protector according to claim 7, wherein the wafer carrier is made of a sapphire wafer, a glass wafer, or a SiC wafer.
